(19) United States
(12) Patent Application Publication
(10) Pub. No.: US 2011/0278566 A1
(43) Pub. Date: Nov. 17, 2011

(54) METHOD OF PATTERNING THIN FILM SOLUTION-DEPOSITED

(75) Inventor: Myeong Kyu LEE, Seoul (KR)

(73) Assignee: INDUSTRY-ACADEMIC COOPERATION FOUNDATION, YONSEI UNIVERSITY, Seoul (KR)

(21) Appl. No.: 13/108,512

(22) Filed: May 16, 2011

(30) Foreign Application Priority Data
May 17, 2010 (KR) 10-2010-45884

(51) Int. Cl. H01L 29/12; H01L 21/20

(52) U.S. Cl. 257/43; 438/104; 257/E21.09; 257/E29.068

(57) ABSTRACT

A method of patterning a solution-deposited thin film is provided. The method includes photoetching a pattern in a laser absorption metal layer by allowing a pulsed laser beam to pass through a spatial optical modulator so that the laser beam is radiated on the metal layer, the pattern corresponding to the spatial optical modulator; solution-depositing an oxide layer over a surface of the substrate that is exposed to an outside and a surface of the patterned metal layer; patterning the solution-deposited oxide layer by radiating a pulsed laser beam directly on the solution-deposited oxide layer without passing through the spatial optical modulator, and heating the metal layer underlying the oxide layer to induce thermo-elastic force, so that the metal layer is detached along with the overlying oxide layer from the substrate.

### CROSS REFERENCE TO RELATED APPLICATION

The present application claims priority from Korean Patent Application Number 10-2010-0045884 filed on May 17, 2010, the entire contents of which application are incorporated herein for all purposes by this reference.

### BACKGROUND OF THE INVENTION

1. Field of the Invention

The present invention relates to a thin film patterning process, and more particularly, to a method that allows high-resolution patterning to be performed on a solution-deposited oxide semiconductor thin film without using either a photoresist or chemical etching.

2. Description of Related Art

Oxide semiconductors have drawn great interest for use in various optoelectronic applications, such as transparent electronics, Light-Emitting Diodes (LEDs) and photodetectors. The main benefit of oxide materials is that they enable low-temperature deposition, which is compatible with plastic substrates, and can provide higher mobilities than amorphous silicon (Si), in addition to the intrinsic characteristic of transparency.

Thin Film Transistors (TFTs) are usually classified by the semiconductor channel materials. A number of research groups have been investigating TFTs based on zinc oxide (ZnO), Zinc-Tin Oxide (ZTO), Indium-Zinc Oxide (IZO), and Indium-Gallium-Zinc Oxide (IGZO), and some devices have revealed field effect mobilities comparable to those of poly-Si TFTs. The channel layers of the TFT can be prepared by many different methods, such as sputtering, pulsed laser deposition, and atomic layer deposition. Solution processing of the semiconductor layers can offer the advantages of simplicity, low cost, and high throughput over conventional vacuum depositions. Thus, organic semiconductors were extensively explored at first. However, the organic semiconductors have fundamental limitations of low mobility, environment-sensitive performance, and unstable long term. Solution-processed TFTs based on ZnO-class inorganic semiconductors have also been reported recently. Since the solution-processed TFTs also exhibit poor performance compared to typical vacuum-processed TFTs, active research is currently underway, particularly in order to improve the mobility and lower the annealing temperature.

Meanwhile, the development of patterning processes is an issue that is no less important than the solution deposition process, because it is very difficult to selectively deposit a solution-state material on a substrate using a shadow mask, even though selective deposition using a shadow mask is possible in a typical vacuum deposition process. Therefore, selective etching based on lithography has to be used. Although conventional lithography can advantageously be used to realize high-resolution patterns, its expensive and complicated procedure overshadows the benefits of the solution process. Although the ultimate goal of studying oxide semiconductors is to realize fully transparent all-oxide devices, the chemical etching associated with lithography may not provide sufficient selectivity among similar oxide materials. In this sense, inkjet printing, in which deposition and patterning are simultaneously accomplished, is an attractive technique. A number of inkjet-printed ZnO-based semiconductors have also been examined recently. However, the problems of low spatial resolution and poor edge resolution still remain as challenges to overcome.

In relation with the patterning of a thin film formed on the surface of a substrate, a Laser-Induced Forward Transfer (LIFT) technique (e.g., U.S. Pat. No. 6,743,556) has been reported. Although this technique is intended to be used to pattern a thin film using a laser, it fails to replace photolithography because its resolution and process rate are limited. Specifically, research using a laser in the process of printing a pattern on a thin film was first proposed by J. Bohandy et al. It was reported that a line pattern having a line width of several tens of μm can be formed on a Si substrate by bringing the Si substrate into contact with a Cu thin film, which is vacuum-deposited on a glass substrate that acts as a source substrate, and then radiating a focused laser beam from an excimer pulse laser (λ=195 nm, pulse width=15 ns) on the thin film through a cylindrical lens. This technique was named Laser-Induced Forward Transfer (LIFT). According to this model, a laser pulse heats an interface portion of the thin film that is in direct contact with the glass, thereby forming a Cu melt at the interface. When the melt front reaches the free surface of the thin film through gradual migration, the interface portion is heated to a boiling point or higher, thereby forming Cu vapors. Under the pressure of the vapors, the melt is transferred to the Si substrate, where the melt is condensed, thereby forming a pattern. Since then, similar research using other metal thin films made of Ag, Au, Al, or the like has been reported. Although conventional LIFT can be useful for forming a pattern of a simple material that can be easily evaporated or melted, it is not appropriate for a material having a complicated structure, or for cases in which the unique properties of a material must be maintained without phase transition. Tolbert et al. disposed a thin absorption layer between a material intended to be transited and a glass substrate, and used pressure resulting from the evaporation of the absorption layer as driving force for transition. Although this technique is advantageous in that the material that is intended to be transited does not evaporate or melt, it is disadvantageous in that an additional process, in which the absorption layer must be additionally formed between the substrate and a thin film, is required. As another technique, a paste is made by mixing a powder material with a high molecule binder, and a pattern is formed by coating a glass substrate with the paste. During transition, the binder is selectively evaporated by absorbing laser energy. The remaining binder, which is not completely evaporated during transition, can be removed through additional heat treatment. Since melting and condensing of the material that is intended to be transited are not performed, it is advantageous in that a film can be printed at a thickness greater than those formed by other LIFT techniques. This technique belongs to the category of LIFT even though it is separately referred to as Matrix-Assisted Pulsed Laser Evaporation Direct-Write (MAPLE DW). Additional procedures, such as paste formation, are required.

Although LIFT is applicable to the transition of polymer and biomaterials as well as inorganic materials, it basically uses the evaporation of a specific material or a matrix mixed therewith through focusing of a pulsed laser beam. This serial or spot-by-spot technique can be useful for forming a regular and periodic pattern, such as a line pattern, having a predetermined width. However, this technique has a limited ability to rapidly form patterns having various shapes and sizes, and it is difficult to control the cross-sectional shape of the pattern. A high power pulse laser is required since instantaneous energy absorption must be high in order to induce the melting or evaporation of a material in a localized area. Printing speed is closely related with the repetition rate of a laser that is used. The repetition rate must be at least several kHz, since the time period between pulses is required to be very short in the case in which one droplet is transited to a receiver substrate using a single pulse. Otherwise, the interval between pulses increases, and a long time is spent for the entire patterning process. For a laser having a fixed amount of average power, the energy of a single pulse must decrease as the repetition rate increases. However, printing requires minimum pulse energy. This means that a laser having a higher power must be used in proportion to the printing speed in order to increase the printing speed.

A patterning process that is actually applicable in industry is required to permit free control over the shape and period of a pattern, and to be economical by virtue of simple and quick. However, patterning techniques that have been devised to date have problems in that they are time-consuming and incur high expenses attributable to complicated multistage processes if the shape and period of a pattern can be controlled, and in that the shape and period of a pattern cannot be freely controlled in the case of self-assembly, in which the process itself is relatively simple.

In addition, other techniques, such as WO 2000-69235 (“MANUFACTURING ELECTRONIC COMPONENTS IN A DIRECT-WRITE PROCESS USING PRECISION SPRAYING AND LASER IRRADIATION”), Korean Patent No. 10-299185 (“APPARATUS AND METHOD OF FORMING CONDUCTIVE PATTERN ON INSULATING SUBSTRATE USING LASER BEAM”), Korean Patent No. 10-792593 (“METHOD AND SYSTEM OF FORMING SINGLE PULSE PATTERN USING ULTRAHIGH PULSE LASER”), Korean Patent No. 10-0475223 (“LASER ADDRESSABLE THERMAL TRANSFER IMAGE DEVICE HAVING INTERMEDIATE LAYER”), and Korean Patent No. 10-0833017 (“METHOD OF FORMING HIGH RESOLUTION PATTERN USING DIRECT PATTERNING”), are known in the related art.

However, the techniques disclosed in the above-mentioned documents are limited in their applicability to the formation of complicated pattern shapes, since they involve serial processing, which fundamentally belongs to the category of the LIFT technique. These techniques also fail to provide a specific solution to the application of a solution-deposited thin film to patterning.

The information disclosed in this Background of the Invention section is only for the enhancement of understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide a method of patterning a thin film, in which a thin film pattern can be performed on a substrate without using either a photoresist or chemical etching, which is required in a photography process of the related art.

Also provided is a method in which a thin film that is formed on a substrate can be patterned through solution processing, for example, spin coating.

Also provided is a method of patterning a thin film, in which a pattern desired by a user can be formed on a solution-processed thin film irrespective of limitations of a shadow mask, that is, without limitations as to size, such as limitations in the size (e.g., 25 μm) of openings formed in the mask.

Also provided is a method of pattering a solution-deposited thin film, in which a pattern having a complicated shape desired by a user can be formed through a simplified process.

Also provided is a method of pattering a thin film, in which an intended pattern can be formed on a thin film that is formed through solution processing, irrespective of the type of a substrate on which the thin film is formed.

An exemplary embodiment of the present invention discloses a method of patterning a solution-deposited thin film, the method including (a) preparing a substrate; (b) forming a laser absorption metal layer on the substrate; (c) photoetching a pattern in the metal layer by allowing a pulsed laser beam, which is output from a pulsed laser beam-radiating means, to pass through a spatial optical modulator so that the laser beam is radiated on the metal layer, the pattern corresponding to the spatial optical modulator; (d) solution-depositing an oxide layer over a surface of the substrate that is exposed to an outside and a surface of the patterned metal layer; and (e) patterning the solution-deposited oxide layer by heating the metal layer underlying the oxide layer to induce thermo-elastic force by radiating a pulsed laser beam, which is output from the pulsed laser beam-radiating means, directly on the solution-deposited oxide layer without passing through the spatial optical modulator, so that the metal layer is detached along with the overlying oxide layer from the substrate.

In an exemplary embodiment, the oxide layer may be transparent to the pulsed laser beam.

In an exemplary embodiment, the oxide layer may be made of Zinc-Tin Oxide (ZTO).

In an exemplary embodiment, the pulsed layer beam may have a frequency on the order of nanoseconds.

In an exemplary embodiment, in the step (d), the oxide layer may be formed by spin coating.

An exemplary embodiment of the present invention discloses a ZTO field effect transistor that includes a silicon (Si) wafer functioning as a gate electrode; a Si oxide layer formed on the gate electrode to function as a gate dielectric; a ZTO oxide layer patterned on the Si oxide layer by the above-described method; and source and drain electrodes formed in the patterned ZTO oxide layer.

According to embodiments of the invention, the solution-deposited oxide semiconductor layer can be patterned so that it has a sharp-edged structure. Furthermore, the pattern can be created to match a desired shape, irrespective of patterning limitations of a shadow mask, since neither a photoresist nor chemical etching is used in the patterning of the thin film.

The methods and apparatuses of the present invention have other features and advantages which will be apparent from, or are set forth in greater detail in the accompanying drawings, which are incorporated herein, and in the following Detailed Description of the Invention, which together serve to explain certain principles of the present invention.

### BRIEF DESCRIPTION OF THE DRAWINGS

FIG. 1A is a view schematically showing a patterning process of the present invention;

FIG. 1B is a scanning electron microscopic (SEM) image showing a patterned ZTO film taken after annealing at 500° C., in which an insert is an SEM image of the surface of the film;

FIG. 2 is optical profiler images showing ZTO line patterns (having a thickness of 160 nm) that are fabricated using a 20 nm-thick Al absorption layer, in which given scales represent the width of individual line patterns;

FIGS. 3A and 3B are optical profiler images showing an Al layer that is photo-etched by three-beam interference and a ZTO film that is inversion-patterned, respectively;

FIG. 4 is an SEM image showing how a ZTO pattern is formed by the dynamic releasing of an Al layer having a honeycomb structure;

FIG. 5 is a graph showing the characteristics of a ZTO TFT having an unpatterned channel layer, in which the drain current (I_{d})-to-gate voltage (V_{g}) relationship is measured under a drain voltage of V_{d}=40V; and

FIG. 6A shows a TFT having a patterned ZTO channel layer and FIGS. 6B and 6C show the characteristics of the TFT.

### DETAILED DESCRIPTION OF THE INVENTION

Reference will now be made in detail to various embodiments of the present invention, examples of which are illustrated in the accompanying drawings and described below. While the invention will be described in conjunction with exemplary embodiments, it is to be understood that the present description is not intended to limit the invention to those exemplary embodiments. On the contrary, the invention is intended to cover not only the exemplary embodiments, but also various alternatives, modifications, equivalents and other embodiments that may be included within the spirit and scope of the invention as defined by the appended claims.

In the following description of the present invention, detailed descriptions of technical constitutions related to thin film patterning that are well known in the art will be omitted.

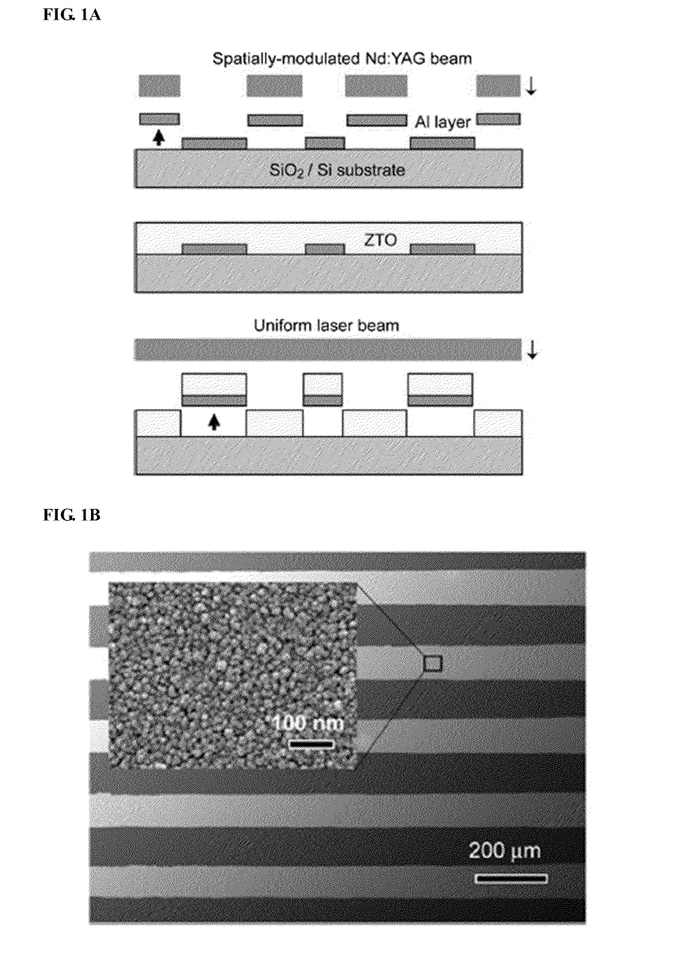

FIGS. 1A and 1B are views schematically showing a process of performing a method of patterning a thin film according to an exemplary embodiment of the present invention.

First, referring to FIG. 1A, an Al thin film layer 20 (having a thickness of 10 nm) was formed on a SiO₂/Si substrate 10. In one embodiment, the thin film layer 20 was formed using a thermal evaporation process. This thermal evaporation process was performed under a pressure of 5×10⁻⁶ Torr without heating the substrate 10. During the formation of the thin film layer, its thickness was monitored using a microbalance and calibrated using an optical profiler.

Afterwards, a laser beam was radiated using a laser system, which is not specifically shown. The laser system is a known laser system that includes a pulsed laser beam-radiating means, which serves as a pulsed laser source, a beam expander, and a spatial optical modulator. Specifically, a pulsed Nd:YAG laser beam (a wavelength of 1064 nm, a pulse width of 6 ns, a repetition ratio of 10 Hz, and maximum average power of 8.5 W) was emitted from the beam-radiating means, and the radiation area of the beam was expanded using the beam expander. Afterwards, the beam was spatially modulated by allowing it to pass through the spatial optical modulator. Subsequently, the beam was radiated on the Al thin film layer, thereby patterning the thin film layer in an intended shape via direct photoetching. In this embodiment, a single pulse was used, and a 0.9 cm output laser beam was radiated on the thin film layer by being expanded through the beam expander (3× or 5×) when necessary. The spatial profile of the incident laser beam can be modified by several techniques such as contact mode, projection mode, and holography without a mask. In the exemplary embodiment of the invention, the metal thin film is made of Al, since Al needs a relatively low pulse energy density. However, it should be understood that in the present invention, the metal that is used is not limited to Al.

Afterwards, a ZTO film 30 (having a thickness of 30 nm) was formed on the patterned Al layer via solution processing, that is, a spin coating process. The ZTO film 30 was formed not only on the patterned Al layer 20, but also on the portion of the substrate 10 that is exposed to the outside as the result of the patterning through the laser radiation. A precursor solution for the spin coating of the ZTO film was synthesized by dissolving 0.03M zinc acetate (Zn(CH₃COO)₂) and 0.03M tin chloride (SnCl₂) in 2-methoxyethanol, separately from each other. In order to get a more stable solution, the precursors were chelated with acetylacetone (CH₃COCH₂COCH₃) at an equivalent molar ratio. The two resultant solutions were then mixed and stirred for 6 hours at room temperature. Finally, the mixed solution was filtered through a 0.2 μm syringe filter. The ZTO film 30 was then formed by spin-coating the precursor solution, in the same fashion as described above. After being dried for 30 minutes at room temperature, the ZTO film 30 was irradiated from above with a single-pulsed uniform Nd:YAG laser beam, in the same fashion as described above. Here, the spatially-modulated Nd:YAG pulsed laser beam is not radiated as in the patterning of the Al thin film layer 20. Rather, a uniform beam that is not spatially expanded, such as a laser beam that is output from the laser beam-radiating means or a laser beam that is produced by expanding the laser beam output from the laser beam-radiating means, is radiated on the ZTO film 30. As a result, as schematically shown in FIG. 1A, the Al layer is detached together with the overlying ZTO film from the substrate, so that a pattern 40 is formed in the ZTO film. Finally, the patterned ZTO film 30 is annealed for 1 hour at 500° C. at an ambient atmosphere. FIG. 1B is the SEM image of the produced ZTO film.

In the present invention, the semiconductor oxide layer, which is formed through the solution processing, is patterned by direct photoetching by employing an ultrashort pulsed laser beam, for the following reasons:

As proposed in the present invention, when a laser beam is radiated on the solution-processed oxide layer, thermo-elastic force is generated in the metal thin film by rapid thermal expansion resulting from the absorption of laser energy. The thermo-elastic force is proportional to the rate of temperature increase, and is not determined by the absolute magnitude of the temperature increase. Therefore, when the total energy of a single pulse is fixed, the thermo-elastic force increases with decreasing pulse width. Since photoetching is possible only when the induced force exceeds the cohesion of the film and its adhesion to the underlying substrate, a shorter pulse is more favorable not only for overcoming the threshold level but also for increasing the size of the area that can be patterned with a single pulse. The inventor observed that direct photoetching is impossible with a Nd:YAG laser pulse having a frequency (pulse width) on the order of milliseconds.

Another reason for using an ultrashort pulse is related to pattern fidelity. If the thin film is irradiated for a longer time, the generated force distribution will be more and more inconsistent with the incident beam profile due to thermal diffusion. Estimating with its thermal diffusivity (8.42×10⁻⁵ m²/s), the diffusion length of Al for 6 ns is about 0.7 μm. This indicates that sub-10 μm patterns are photoetchable, and maintain a fairly good fidelity with the transferred pattern image.

Since the ZTO film 30 is transparent in the near-infrared range, most of the incident laser energy passes through the ZTO to arrive at the underlying Al layer 20. Considering the very short penetration depth of the near-infrared wave into the metal, a large portion of the pulse energy will be dissipated near the top surface of the Al layer. Since the thermal diffusion length is much larger than its thickness (20 nm), the whole Al layer can be heated in the duration of a single pulse. Thermo-elastic force will be exerted on the Al layer to detach it from the substrate 10. Consequently, the Al layer 20 and the ZTO film 30, which is spin-coated on the Al layer 20, are detached from the substrate 10, thereby leaving a patterned structure of ZTO.

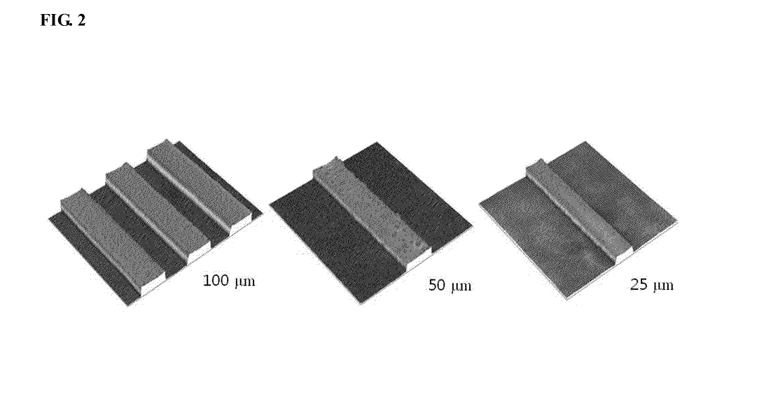

FIG. 2 is optical profiler images showing ZTO line patterns having different widths that are fabricated using a 20 nm-thick Al absorption layer. All of them exhibit clear-cut edges. This implies that the solution-processed ZTO film has relatively weak cohesion compared to its adhesion to the substrate, as is expected from the nanostructure shown in FIG. 1B. If the film cohesion is rather strong with respect to the film-substrate cohesion, it would be almost impossible to pattern sharp-edged fine structures, because the portion of the ZTO area overlying the substrate, which does not directly overlie the Al layer, might also be removed therewith. In an extreme case, the entire ZTO film could be peeled off from the substrate even if the driving force initiated from the underlying metal layer is space-selective.

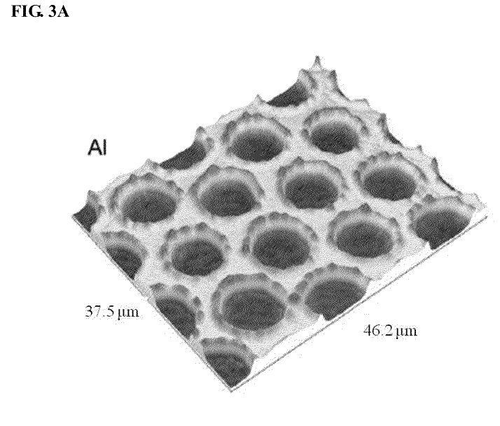

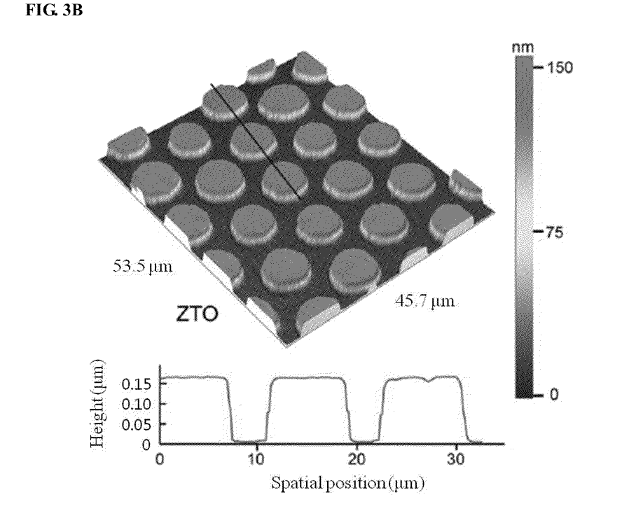

Taking the mechanism of this layer dynamic process into account, the fidelity and quality of the final ZTO pattern will be dependent on the feature size of the metal layer that is used. The ZTO patterns shown in FIG. 2 were fabricated using an Al film that was photoetched using a shadow mask placed over the Al film. Since the etched Al layer needs to be removed through openings in the shadow mask, the achievable minimum feature size in this case is limited to the opening size of the mask. Although projecting a pattern image by a combination of a photomask and a lens can provide a higher resolution, this projection mode requires very accurate control over the optical setup. In order to estimate how small features can be obtained by the dynamic release process of the present invention, the inventor employed a holographically patterned Al layer as the absorption layer. An Al layer was directly photoetched by generating three interfering beams using a single refracting prism (a refractive index of 1.48) having a trigonal pyramidal shape. A ZTO film was spin-coated over the Al layer and was irradiated with a uniform beam (see FIG. 1A). FIGS. 3A and 3B are the optical profiler images of the patterned Al layer and the patterned ZTO film. As expected, the Al film exhibited a honeycomb structure after being photoetched, and a clear inversion pattern was created in the ZTO film. It should be noted that the ZTO pattern reveals sharp edges even though the feature sizes are less than 10 μm. That is, it can be understood that the present invention can overcome the limit that can be patterned using a shadow mask.

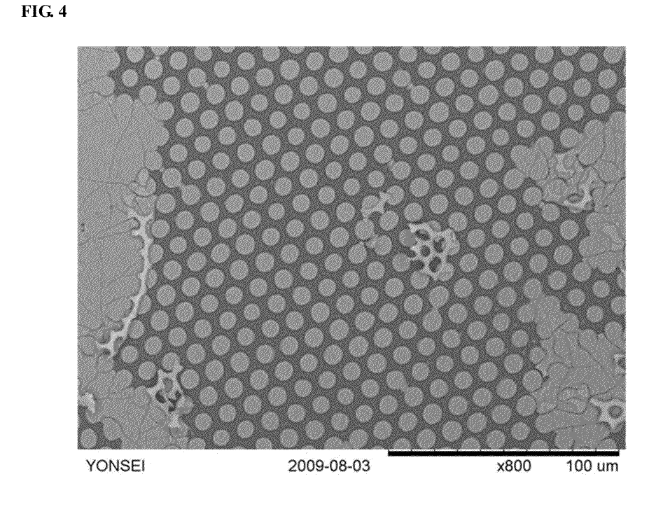

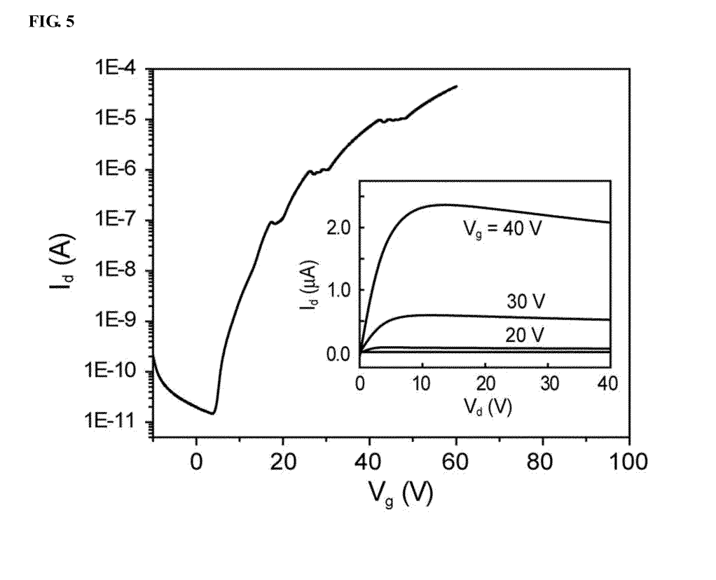

The SEM image in FIG. 4 pictorially shows a dynamic release process for ZTO patterning. The incident laser beam might be absorbed by the Si wafer after having passed through transparent ZTO and SiO₂ layers. However, the damage threshold of Si was found to be much higher than the pulse energy density required for ZTO patterning, and thus no damage to the substrate was observed. The inventor also found that the threshold pulse energy density was not much influenced by the ZTO thickness. A pulse energy density of 270 mJ/cm² was required to detach a 30 nm-thick ZTO film together with a 20 nm-thick Al layer. When the ZTO films were made thicker, that is, to thickness of 80 nm and 400 nm, with a fixed Al thickness of 20 nm, the pulse energy density increased to 290 mJ/cm² and 340 mJ/cm², respectively. This indicates that the incident laser energy is mostly used to induce thermo-elastic force in the Al layer, with a small portion thereof needed to break the internal bonds of the ZTO film. These threshold levels made it possible to pattern over a few square centimeters using a single pulse having a maximum energy level of 850 mJ.

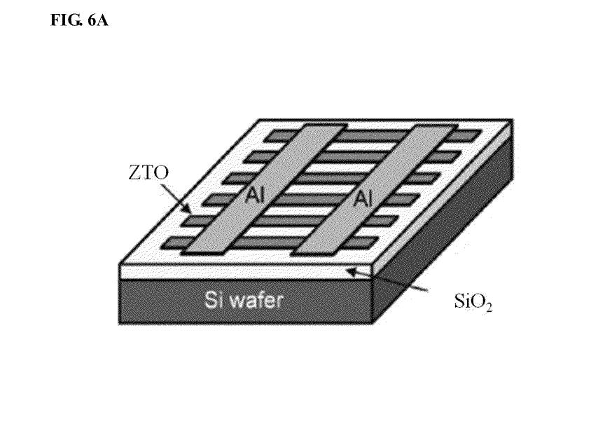

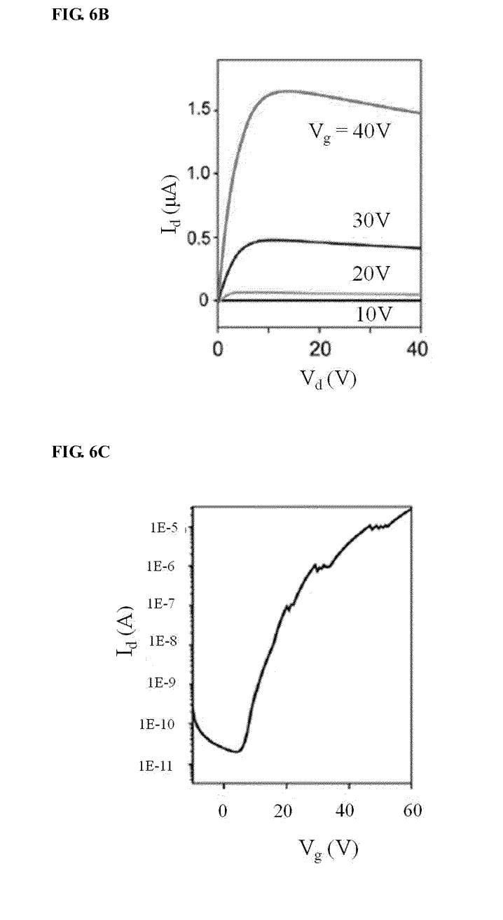

A critical issue related to the laser thin film processing of the present invention is whether or not it adversely influences the material properties and device performance. In order to investigate the feasibility of this process for electronic devices, the inventor fabricated ZTO TFTs and examined their characteristics. A heavily-doped p-type Si wafer was used as the gate electrode, and a thermally grown SiO₂ layer (200 nm thick) was used as a gate dielectric. First, the inventor fabricated a reference TFT. A 30 nm-thick ZTO active layer was spin-coated over the SiO₂ dielectric layer at room temperature, followed by sintering for 1 hour at 500° C. Al source and drain electrodes (40 nm thick) were then deposited on a ZTO channel by thermal evaporation so that the device has a channel length of L=100 μm and a channel width of L=100 μm. The characteristics of the TFT fabricated as above are given in FIG. 5. FIG. 5 shows a saturation mobility of 1.0×10⁻¹ cm²V⁻¹s⁻¹, an ON/OFF ratio of 3.2×10⁶, and an off current of 1.4×10⁻¹¹ A. The obtained mobility was rather low compared to those reported in the existing literature (e.g., S. Seo. C. Choi, Y. Hwang, and B. Bae, J. Phys. D: Apply. Phys. 2009, 42, 035106). In order to see the effect of laser patterning of the present invention, a ZTO layer having a thickness of 30 nm was prepared using the same precursor solution, and was patterned in the form of stripes having a line width of 100 μm and a period of 200 μm (refer to FIG. 6A). In order to pattern the ZTO layer, an Al metal layer was first patterned, and the patterned Al metal layer was used as an absorption layer for the ZTO patterning process. The source and drain electrodes were evaporated orthogonally to the stripes. The channel length and total channel width were made the same as those of the reference. FIGS. 6B and 6C show the measured characteristics, with a mobility of 0.76×10⁻¹ cm²V⁻¹s⁻¹, an ON/OFF ratio of 1.5×10⁶, and an off current of 1.9×10⁻¹¹ A. These parameters are slightly smaller than those from an unpatterned TFT. The high on/off ratio and the low off-current level indicate that the Al layer was completely removed in the ZTO patterning process. The inventor investigated another set of TFTs with a finer channel pattern, and was able to confirm that no significant degradation of the device performance was induced by this laser dynamic release process. The characteristics of all the investigated TFTs are summarized in Table 1 below. Here, the I-V curves of the TFTs were measured using a semiconductor parameter analyzer (HP 4156A, MS-Tech).

TABLE 1

| | W | | Mobility | ON/OFF | OFF-current |
|---|---|---|---|---|---|
| L (μm) | (mm) | ZTO channel | (cm²/V · s) | ratio | (A) |
| 100 | 4 | No patterning | 1.0 × 10⁻¹ | 3.2 × 10⁶ | 1.42 × 10⁻¹¹ |
| 100 | 4 | Stripe | 0.76 × 10⁻¹ | 1.5 × 10⁶ | 1.91 × 10⁻¹¹ |
| | | l = 100 μm | | | |
| | | p = 200 μm | | | |
| 50 | 1.5 | No patterning | 1.7 × 10⁻¹ | 7.7 × 10⁶ | 0.84 × 10⁻¹¹ |
| 50 | 1.5 | Stripe | 1.4 × 10⁻¹ | 4.0 × 10⁶ | 1.02 × 10⁻¹¹ |
| | | l = 50 μm | | | |
| | | p = 100 μm | | | |

In Table 1 above, “l” and “p” represent the line width and period of the stripe pattern, respectively.

As set forth above, according to the present invention, it is possible to fabricate solution-processed oxide semiconductor thin film patterns having high spatial and edge resolutions using a laser process. The method of the present invention utilizes a photoetched metal pattern as the dynamic release layer, and an oxide film deposited over the photoetched metal pattern is selectively removed by thermo-elastic force induced in the underlying metal layer. It was possible to fabricate sharp-edged ZTO patterns on the micrometer scale over a few square centimeters using a single Nd:YAG laser pulse. Block-to-block patterning, with the substrate stationed on an automatic translation stage, would greatly enlarge the total patterning area. TFTs fabricated with the patterned ZTO active channel showed device characteristics comparable to those of unpatterned references, demonstrating the potential of the process of the present invention for application to the manufacture of electronic devices. Furthermore, the method of the present invention is free from photoresist and chemical etching steps, and is applicable to all kinds of substrates. That is, the method of the present invention performs patterning by radiating a laser beam from the front of a metal layer that is to be released and a solution-deposited oxide semiconductor layer, and has advantages in that patterning is not limited to the material of the substrate, irrespective whether the substrate is transparent or opaque. Furthermore, unlike the serial or focused laser radiation of the related art, a pattern having an intended shape can be formed through radiation using a single laser.

The foregoing descriptions of specific exemplary embodiments of the present invention have been presented for the purposes of illustration and description. They are not intended to be exhaustive or to limit the invention to the precise forms disclosed, and obviously many modifications and variations are possible in light of the above teachings. The exemplary embodiments were chosen and described in order to explain certain principles of the invention and their practical application, to thereby enable others skilled in the art to make and utilize various exemplary embodiments of the present invention, as well as various alternatives and modifications thereof. It is intended that the scope of the invention be defined by the Claims appended hereto and their equivalents.

1. A method of patterning a solution-deposited thin film, the method comprising:
(a) preparing a substrate;
(b) forming a laser absorption metal layer on the substrate;
(c) photoetching a pattern in the metal layer by allowing a pulsed laser beam, which is output from a pulsed laser beam-radiating means, to pass through a spatial optical modulator so that the laser beam is radiated on the metal layer, the pattern corresponding to the spatial optical modulator;
(d) solution-depositing an oxide layer over a surface of the substrate that is exposed to an outside and a surface of the patterned metal layer; and
(e) patterning the solution-deposited oxide layer by radiating a pulsed laser beam, which is output from the pulsed laser beam-radiating means, directly on the solution-deposited oxide layer without passing through the spatial optical modulator, and thus heating the metal layer underlying the oxide layer to induce thermo-elastic force, so that the metal layer is detached along with the overlying oxide layer from the substrate.

2. The method according to claim 1, wherein the oxide layer is transparent to the pulsed laser beam.

3. The method according to claim 2, wherein the oxide layer is made of Zinc-Tin Oxide (ZTO).

4. The method according to claim 1, wherein the pulsed layer beam has a frequency on the order of nanoseconds.

5. The method according to claim 1, wherein in the step (d), the oxide layer is deposited by spin coating.

6. A ZTO field effect transistor comprising:
a silicon (Si) wafer functioning as a gate electrode;
a Si oxide layer formed on the gate electrode to function as a gate dielectric;
a ZTO oxide layer formed and patterned on the Si oxide layer by the method according to claim 1; and
source and drain electrodes formed on the patterned ZTO oxide layer.
